(19) United States
(12) Patent Application Publication
(10) Pub. No.: US 2026/0303053 A1
(43) Pub. Date: Oct. 1, 2026

(54) HIGH FREQUENCY POWER SUPPLY SYSTEM

(71) Applicant: DAIHEN Corporation, Osaka (JP)

(72) Inventors: Asei MIYAMOTO, Osaka (JP); Shuji OMAE, Osaka (JP)

(21) Appl. No.: 19/633,223

(22) Filed: Mar. 30, 2026

(30) Foreign Application Priority Data
Mar. 31, 2025 (JP) 2025-059197

(51) Int. Cl. H03H 7/38; H02M 1/00; H01J 37/32

(52) U.S. Cl. CPC H03H 7/38; H02M 1/0003; H01J 37/32183

(57) ABSTRACT

The high frequency power supply system includes: a high frequency power output circuit 10 that outputs high frequency power; a common sensor 14 provided on a load side of the high frequency power output circuit; a power controller 13 that acquires information related to the high frequency power calculated based on information detected by the common sensor 14 and controls a power value of the high frequency power; drivers 33 and 34 for changing a variable value of variable impedance elements 321 and 322 in a matching circuit 32; and a matching controller 39 that acquires a reflection coefficient ρ or a load-side impedance Z calculated based on the information detected by the common sensor 14 and gives a command signal for changing the variable value of the variable impedance elements 321 and 322 to the drivers so as to decrease the reflected wave power.

### CROSS-REFERENCE TO RELATED APPLICATIONS

This application is based upon and claims the benefit of priority from Japanese Patent Application No. 2025-059197, filed on Mar. 31, 2025, the entire contents of which are incorporated herein by reference.

### FIELD

The present disclosure relates to a high frequency power supply system.

### BACKGROUND

For example, a high frequency power supply system used in a plasma processing apparatus supplies high frequency power having a fundamental frequency in a Radio Frequency (RF) band (RF band) from a high frequency power source to a load (for example, a plasma processing apparatus).

In addition, there is provided an impedance matcher (also denoted as an impedance matching apparatus) between the high frequency power source and the load. The impedance matcher performs an operation of matching impedance between the high frequency power source and the load by adjusting a variable value (for example, capacitance or inductance) of an internal variable impedance element so as to decrease the power value of reflected wave power on a high frequency power source side (for example, the input end) in the impedance matcher. The operation of changing the variable value of the variable impedance element to match the impedance in this manner is denoted as a matching operation.

The high frequency power source and the impedance matcher each include a dedicated sensor, and perform control based on information detected by each sensor.

The sensor used in the high frequency power source is disposed at the output end of the high frequency power source, and the sensor used in the impedance matcher is disposed on the high frequency power source side (for example, the input end) of the impedance matcher. Accordingly, the individual sensors are disposed at physically different positions via a transmission line.

The high frequency power source calculates information related to the high frequency power output from the high frequency power source based on the information detected by the sensor provided at the output end, and controls the power value of the high frequency power output from the high frequency power source using the information related to the calculated power value.

In addition, the impedance matcher calculates a reflection coefficient or a load-side impedance based on information detected by a sensor provided on a high frequency power source side (for example, its input end) and uses the calculated reflection coefficient or load-side impedance as load information, and uses the load information to give the driver a command signal for changing a positional relationship between electrodes or between windings of the variable impedance element so as to decrease reflected wave power to perform a matching operation.

### SUMMARY

As described above, the high frequency power source and the impedance matcher each include a dedicated sensor, and perform control based on information detected by the dedicated sensor. However, there is a possibility that a slight difference occurs in impedance (hereinafter, load-side impedance) when the load side is viewed from each sensor.

This is because the high frequency power output from the high frequency power source has a high fundamental frequency and a short wavelength, and thus even when the transmission line connecting the high frequency power source and the impedance matcher is relatively short, the load-side impedance is affected according to the length of the transmission line. Further, harmonic components generated when plasma is generated in the load also affect the information detected by each sensor.

As a result, there is a possibility that a difference between the sensors occurs in the information (for example, a power value, a reflection coefficient) calculated using the information detected by each sensor. However, since the high frequency power source and the impedance matcher have different control targets, there is no problem in terms of control even when the above difference occurs.

Meanwhile, for the purpose of analyzing the operating status of the high frequency power supply system, etc., information (for example, a power value, a reflection coefficient) calculated using information detected by each sensor is monitored in some cases. In such a case, when there is a difference in information (for example, a power value, a reflection coefficient) calculated based on the information detected by each sensor, there might be difficulty in deciding which information is to be adopted, causing confusion.

In order to solve this problem, attempts are made in some cases to reduce the influence of the above difference by adjusting the length of the transmission line (coaxial cable, etc.) connecting the high frequency power source and the impedance matcher to each other. However, this adjustment work needs to be performed in a state where the high frequency power source and the impedance matcher are connected to each other using a transmission line (coaxial cable, etc.) and a load is connected to a subsequent stage of the impedance matcher, requiring a lot of man-hours.

The present disclosure provides a high frequency power supply system capable of suppressing occurrence of a problem of having a difference in information calculated based on information detected by individual dedicated sensors of the high frequency power source and the impedance matcher.

### BRIEF DESCRIPTION OF THE DRAWINGS

FIG. 1 is a diagram illustrating a configuration example of a high frequency power supply system;

FIG. 2 is a diagram illustrating another configuration example of the high frequency power supply system; and

FIG. 3 is a diagram illustrating another configuration example of the matching circuit; and

### DETAILED DESCRIPTION

Hereinafter, an embodiment of a high frequency power supply system according to the present disclosure will be described with reference to the drawings.

### Embodiment

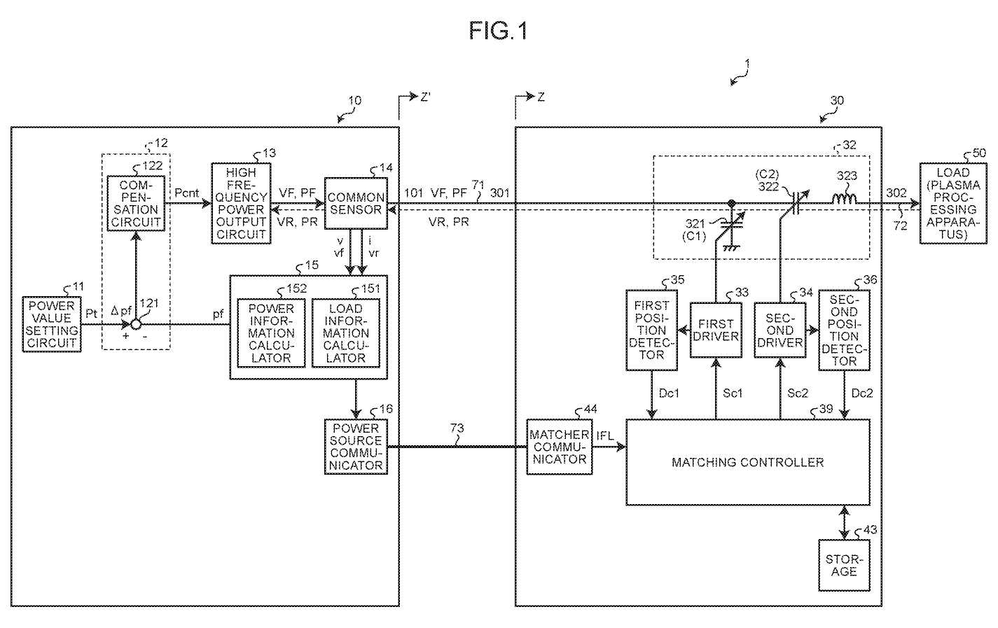

FIG. 1 is a diagram illustrating a configuration example of a high frequency power supply system.

A high frequency power supply system 1 is an apparatus that outputs high frequency power having a fundamental frequency (frequency of fundamental wave) in a Radio Frequency (RF) band from a high frequency power source 10, and supplies the high frequency power to a load 50 (for example, a plasma processing apparatus) via an impedance matcher 30.

In the present specification, the voltage component of the high frequency power is denoted as a high frequency voltage, and the current component of the high frequency power is denoted as a high frequency current. In addition, a high frequency voltage from the high frequency power source 10 to the load 50 is defined as a forward wave voltage VF, a high frequency voltage reflected from the load 50 side and returned to the high frequency power source 10 is defined as a reflected wave voltage VR, high frequency power from the high frequency power source 10 to the load is defined as a forward wave power PF, and high frequency power reflected from the load side and returned to the high frequency power source 10 is defined as a reflected wave power PR. In FIG. 1, reflected wave voltage VR and reflected wave power PR are indicated by broken lines.

Additionally, in the present specification, the power value of the forward wave power PF is defined as a forward wave power value pf, the power value of the reflected wave power PR is defined as a reflected wave power value pr, and the power value obtained by subtracting the reflected wave power value pr from the forward wave power value pf is defined as a load-side power value pL.

In the present specification, a reflection coefficient represented by a ratio of the reflected wave voltage VR to the forward wave voltage VF (reflected wave voltage VR/forward wave voltage VF) is denoted as ρ, and an absolute value (magnitude) of the reflection coefficient ρ is denoted as Γ. Practically, the reflection coefficient ρ is calculated using a forward wave voltage detection signal vf and a reflected wave voltage detection signal vr to be described below, by specifically calculating the reflected wave voltage detection signal vr/the forward wave voltage detection signal vf.

In addition, the high frequency power source 10 can decrease the reflected wave power value pr by changing the frequency of the forward wave power PF (forward wave voltage VF) to be output. Hereinafter, this function is denoted as "frequency matching". When the frequency matching operation is performed, the fundamental frequency of the forward wave voltage VF is not constant but varies. However, the expression of the fundamental frequency will be used including a case where the fundamental frequency varies.

Furthermore, the high frequency power source 10 performs, in some cases, frequency modulation control in order to decrease the reflected wave power value pr caused by InterModulation Distortion (IMD), for example. The fundamental frequency of the forward wave voltage VF is not constant but varies even in the case where the frequency modulation control is performed. Still, the expression of the fundamental frequency will be used.

The high frequency power source 10 performs feedback control so as to decrease the error between the forward wave power value pf and the target power value pt. Such power control is denoted as forward wave power constant control (PF constant control). Feedback control can also be performed so as to decrease the error between the load-side power value pL and the target power value pt. Such power control is denoted as load-side power constant control (PL constant control). The following will describe a case where the forward wave power constant control is performed, as an example.

The forward wave voltage VF has, for example, a relatively high fundamental frequency suitable for generating plasma. The fundamental frequency is 40.68 MHz, for example. Naturally, the fundamental frequency is not limited to 40.68 MHz, and may be a frequency in an industrial RF band such as 13.56 MHz or 27.12 MHz.

The forward wave voltage VF may have a relatively low fundamental frequency suitable for ion acceleration, for example The fundamental frequency in this case is 400 kHz, for example. Naturally, the fundamental frequency is not limited to 400 kHz, and may be other frequencies. In this manner, the fundamental frequency of the forward wave voltage VF can be various frequencies depending on the application.

As illustrated in FIG. 1, the high frequency power supply system 1 includes a high frequency power source 10 and an impedance matcher 30. The high frequency power supply system 1 may use a plurality of (for example, two) high frequency power sources 10. For example, there are cases of using a first high frequency power source having a fundamental frequency of the forward wave power PF (forward wave voltage VF) of 40.68 MHz and using a second high frequency power source having a fundamental frequency of the forward wave power PF (forward wave voltage VF) of 400 kHz. In this case, the first high frequency power source will supply high frequency power to the load 50 via the first impedance matcher, while the second high frequency power source will supply high frequency power to the load 50 via the second impedance matcher. However, as illustrated in FIG. 1, the present embodiment will describe an exemplary case where the high frequency power supply system 1 uses one high frequency power source 10.

The high frequency power source 10 amplifies a high frequency signal output from an oscillation unit (oscillator) (not illustrated), outputs and supplies the high frequency power (forward wave power) having an output frequency in an RF band to the load 50. The high frequency power output from the high frequency power source 10 is supplied to the load 50 via a transmission line 71, the impedance matcher 30, and a transmission line 72. The transmission line 71 can be implemented by using, for example, a coaxial cable or a coaxial tube. The transmission line 72 can be implemented by using a load connection member formed with a shielded copper plate, for example. The transmission lines 71 and 72 are different in length, etc. depending on the environment in which the high frequency power supply system 1 is applied and the use conditions.

The impedance matcher 30 matches the impedance between the high frequency power source 10 and the load 50. More specifically, for example, when the impedance (output impedance) when viewing the high frequency power source 10 side from the output end of the high frequency power source 10 is designed to be 50 Ω, for example, and the high frequency power source 10 is connected to the input end of the impedance matcher 30 by the transmission line 71 having a characteristic impedance of 50 Ω, the impedance matcher 30 converts the impedance when viewing the load 50 side from the high frequency power source side (for example, the input end) in the impedance matcher 30 into 50 Ω.

The load 50 is a plasma processing apparatus, for example. The plasma processing apparatus is an apparatus that includes a processing unit and is provided for processing (etching, CVD, etc.) a workpiece such as a wafer or a liquid crystal substrate loaded into the processing unit. In order to process a workpiece, the load 50 introduces a plasma discharge gas into the processing unit, and applies high frequency power (high frequency voltage) supplied from the high frequency power source 10 to the plasma discharge gas, allowing the plasma discharge gas described above to discharge and transition from a non-plasma state to a plasma state. The workpiece is processed using the plasma.

Details of high frequency power source 10

Hereinafter, a configuration of the high frequency power source 10 will be described with reference to FIG. 1.

The high frequency power source 10 includes a power value setting unit 11, a power value controller 12, a high frequency power output circuit 13, a common sensor 14, an information calculator 15, and a power source communicator 16. The power value controller 12 includes a comparison unit 121 and a compensation unit 122. Incidentally, an output terminal is normally provided at the output end 101 of the high frequency power source 10, but is not illustrated.

The high frequency power output circuit 13 amplifies a high frequency signal output from an oscillation unit (oscillator) (not illustrated) and outputs high frequency power (forward wave power) having an output frequency in an RF band. At that time, since the output level of the high frequency power output circuit 13 is controlled based on a control signal Pcnt from the power value controller 12, it is possible to output high frequency power having a desired power value.

The common sensor 14 is provided on the load side with respect to the high frequency power output circuit 13, and detects information for calculating the load-side impedance Z when the load 50 side is viewed from the position of the common sensor 14 or information for calculating the reflection coefficient ρ at the position of the common sensor 14. Since the load-side impedance Z and the reflection coefficient ρ can be mutually converted, either of them may be detected.

In the case of calculating the load-side impedance Z, for example, a voltage detector and a current detector are used as the common sensor 14. In this case, the voltage at the position of the common sensor 14 is detected by the voltage detector, and a voltage detection signal v is output as the detection signal. In addition, a current at the position of the common sensor 14 is detected by a current detector, and a current detection signal i is output as the detection signal. The voltage detection signal v and the current detection signal i are output to the information calculator 15.

When calculating the reflection coefficient ρ at the position of the common sensor 14, for example, a directional coupler is used as the common sensor 14. In this case, the forward wave voltage VF output from the high frequency power output circuit 13 is detected, the forward wave voltage detection signal vf is output as the detection signal, the reflected wave voltage VR reflected from the load 50 side and returning is detected, and the reflected wave voltage detection signal vr is output as the detection signal. The forward wave voltage detection signal vf and the reflected wave voltage detection signal vr are output to the information calculator 15.

Note that an A/D converter (not illustrated) may be provided between the common sensor 14 and the information calculator 15. In addition, a filter for removing unnecessary signal components (for example, harmonic components) may be provided between the common sensor 14 and the information calculator 15. At this time, a filter method is to be appropriately selected.

The information calculator 15 includes a load information calculator 151 and a power information calculator 152.

The load information calculator 151 can calculate the reflection coefficient ρ or the load-side impedance Z based on the detection signal output from the common sensor 14. When these pieces of information are defined as the load information IFL, the information calculator 15 can output the load information IFL to a matching controller 39 of the impedance matcher 30. Note that transmission from the information calculator 15 to the matching controller 39 is performed via the power source communicator 16, a communication cable 73, and a matcher communicator 44 of the impedance matcher 30. It is not necessary to calculate all the load information IFL. For example, when the load-side impedance Z is not used for control, the load-side impedance Z need not be calculated.

The power information calculator 152 can calculate and output the forward wave power value pf, the reflected wave power value pr, the load-side power value pL, and the reflection coefficient absolute value Γ based on the detection signal output from the common sensor 14. Since the information related to the high frequency power is information necessary for controlling the high frequency power source 10, the information is output to the power value controller 12. Note that there is no need to calculate all the information related to the high frequency power. For example, when the load-side power value pL is not used for control, the load-side power value pL need not be calculated.

In addition, the information related to the high frequency power can be output to the matching controller 39 of the impedance matcher 30. The impedance matcher 30 can utilize the information related to the high frequency power for control. For example, the impedance matcher 30 may start the matching operation when the forward wave power value pf exceeds a prescribed threshold.

Since calculation of the information described above is performed by known methods, a detailed description is omitted, but the information can be calculated as follows, for example.

### 1. Reflection coefficient ρ

The reflection coefficient ρ can be calculated by, for example, the reflected wave voltage detection signal vr/the forward wave voltage detection signal vf. The absolute value (magnitude) of the reflection coefficient ρ is defined as a reflection coefficient absolute value Γ.

### 2. Load-side impedance Z

The load-side impedance Z can be calculated by, for example, the voltage detection signal v/the current detection signal i. The load-side impedance Z can be calculated based on, for example, the magnitude of the voltage detection signal v, the magnitude of the current detection signal i, and a phase difference θ between the voltage detection signal v and the current detection signal i. Note that the reflection coefficient ρ and the load-side impedance Z can be mutually converted. Therefore, only either the reflection coefficient ρ or the load-side impedance Z will be described below in some cases.

### 3. Forward wave power value pf

The forward wave power value pf can be calculated by, for example, the forward wave voltage detection signal vf^2/R (R: gain corresponding to resistance value).

### 4. Reflected wave power value pr

The reflected wave power value pr can be calculated by, for example, the reflected wave voltage detection signal vr^2/R (R: gain corresponding to resistance value).

### 5. Load-side power value pL

The load-side power value pL can be calculated based on the forward wave power value pf and the reflected wave power value pr calculated above. The load-side power value pL can be calculated by, for example, the forward wave power value pf- the reflected wave power value pr (subtracting the reflected wave power value pr from the forward wave power value pf).

### 6. Reflection coefficient absolute value Γ

The reflection coefficient absolute value Γ may be calculated based on the forward wave power value pf and the reflected wave power value pr. The reflection coefficient absolute value Γ may be calculated by √ (reflected wave power value pr/forward wave power value pf), for example.

In the present embodiment, since the forward wave power constant control is performed in the high frequency power source 10, the information calculator 15 outputs the calculated forward wave power value pf to the power value controller 12. However, when the load-side power constant control is performed, the calculated load-side power value pL is to be output to the power value controller 12. In addition, the reflection coefficient absolute value Γ may be used in some cases, but the description will be omitted.

The power value setting unit 11 sets a target power value pt of the forward wave power PF to be output from the high frequency power source 10 (high frequency power output circuit 13), and outputs the target power value pt to the power value controller 12.

As described above, the power value controller 12 includes the comparison unit 121 and the compensation unit 122.

The comparison unit 121 subtracts the forward wave power value pf from the target power value pt, and outputs a subtraction result to the compensation unit 122 as error information Δpf.

The compensation unit 122 generates a control signal Pcnt for controlling the power value (forward wave power value pf) of the forward wave power PF according to the error information Δpf, and outputs the control signal Pcnt to the high frequency power output circuit 13.

In one example, the control signal Pcnt is a control signal for controlling the amplitude of the forward wave voltage VF. In this case, the amplitude of the forward wave voltage VF is adjusted by the control signal Pcnt, making it possible to adjust the forward wave power value pf. For example, when the target power value pt is 1,000 [W] and the forward wave power value pf is 950 [W], 50 [W] is insufficient with respect to the target power value pt. Accordingly, the compensation unit 122 determines and outputs the magnitude of the amplitude control signal Pcnt so as to increase the forward wave power value pf to be supplied to the load 50 by 50 [W]. Such control of the forward wave power PF can be performed by using a known method such as PI control or PID control, for example.

The power source communicator 16 communicates with the matcher communicator 44 via the communication cable 73. In the present embodiment, the information calculated by the information calculator 15 is transmitted to the matcher communicator 44. The transmitted information is transmitted from the matcher communicator 44 to the matching controller 39. Communication with the impedance matcher 30 is performed by using RS485 communication or communication using an optical fiber, for example, although the communication method is not limited.

While the present embodiment describes communication with the impedance matcher 30, the communication is not limited thereto. For example, communication with a higher-level control apparatus can be performed. In a case where communication with a higher-level control apparatus is performed, for example, the target power value pt can be received from the higher-level control apparatus. In addition, the information calculated by the information calculator 15 can be transmitted to the higher-level control apparatus.

### Details of impedance matcher 30

The impedance matcher 30 includes a matching circuit 32, a first driver 33, a second driver 34, a first position detector 35, a second position detector 36, a load information calculator 151, a matching controller 39, a storage 43, and a matcher communicator 44. Note that an input terminal and an output terminal are normally provided at the input end 301 and the output end 302 of the impedance matcher 30, respectively, although not illustrated.

The matching circuit 32 is provided between the matcher sensor 31 and the load 50. The matching circuit 32 internally includes, for example, a variable impedance element such as a variable capacitor (also denoted as a variable capacitor) capable of changing capacitance (electrostatic capacitance), and is configured to change a variable value (capacitance for variable capacitor, inductance for variable inductor) of the variable impedance element in accordance with a command from the matching controller 39 to be described below, making it possible to adjust the load-side impedance Z when the load 50 side is viewed from the high frequency power source 10 side (for example, the input end) in the impedance matcher 30.

An impedance Z' when viewing the load 50 side from the output end of the high frequency power source 10 is substantially the same as the load-side impedance Z. Strictly speaking, both are different depending on the length of the transmission line 71, etc., but in the present embodiment, it is assumed that the error is an allowable range in practical use.

In some cases, a variable inductor is provided as the variable impedance element. In addition, a driver such as a motor is provided to change a variable value of the variable impedance element in accordance with a command from the matching controller 39. In addition to the variable impedance element, an inductor having a fixed inductance value is provided in many cases. In addition, a capacitor having a fixed capacitance value is provided in some cases.

The matching circuit 32 illustrated in FIG. 1 is an example of the matching circuit.

The matching circuit 32 of FIG. 1 includes: a first variable capacitor 321 provided between the input end of the impedance matcher 30 and the ground; a second variable capacitor 322 provided between the output end of the matcher sensor 31 and the load 50; and an inductor 323 provided between the second variable capacitor and the load 50 and having a fixed inductance value. The capacitance of the first variable capacitor 321 is represented by C1, and the capacitance of the second variable capacitor 322 is represented by C2.

The first variable capacitor 321 and the second variable capacitor 322 are variable capacitors of a type that uses a driver such as a motor and changes a positional relationship of electrodes to change the capacitance. For example, as described in JP 2024-095370 A and JP 5-63604 A, an electrode of a variable capacitor includes a fixed electrode and a movable electrode, and when a position of the movable electrode is changed using a driver such as a motor, the area of the counter electrode changes. Naturally, the variable capacitor is not limited to such a type. For example, it is also allowable to use a type in which the distance between the electrodes is changed when the position of the movable electrode is changed.

In the first variable capacitor 321 and the second variable capacitor 322, for example, the position of the movable electrode is changed by rotating a rotation shaft connected to the movable electrode by a driver such as a motor. Therefore, the position of the movable electrode can be known by detecting the rotation angle of the rotation shaft. The rotation angle of the rotation shaft can be detected using an encoder, for example. That is, the positional relationship regarding the electrodes can be detected by detecting the rotation angle of the rotation shaft.

The rotation shaft is designed to change the capacitance from a minimum value to a maximum value, for example, at 10 rotations (3600 degrees). However, in practice, in consideration of the variation in capacitance of the variable capacitor, the variable capacitor is designed to be able to perform 10+α rotations (for example, 12 rotations), and is designed to achieve a prescribed capacitance with 10 rotations out of 12 rotations.

For example, in the case of a variable capacitor having a minimum capacitance of 100 pF and a maximum capacitance of 1,300 pF as catalog values, the variable capacitor is designed to achieve the capacitance in the range 200 pF to 1,200 pF at 10 rotations. Accordingly, the ranges of 100 pF to 200 pF and 1,200 pF to 1,300 pF are not used in the matching operation. That is, when the matching operation is performed, 200 pF is the minimum capacitance, and 1,200 pF is the maximum capacitance.

Therefore, when the matching operation is performed, the rotation angle of the rotation shaft when the capacitance is 200 pF is set to 0 degree in terms of control. Practically, for example, the rotation angle rotated by +1 from the rotation angle of the rotation shaft at the time of the minimum capacitance (100 pF) in terms of structure of the variable capacitor may be set to 0 degrees in terms of control.

Similarly, the rotation angle of the rotation shaft when the capacitance is 1,200 pF is set to 3,600 degrees in terms of control. Practically, for example, the rotation angle rotated by -1 from the rotation angle of the rotation shaft at the time of the maximum capacitance (1,300 pF) in terms of structure of the variable capacitor may be set to 3600 degrees in terms of control.

Due to such a relationship, in order to set the rotation angle of the rotation shaft to 0 degrees in terms of control, it is only required to once set the rotation angle of the rotation shaft to the rotation angle (0 degrees in terms of structure) at which the rotation angle becomes the minimum capacitance in terms of structure, and then rotate the rotation shaft to 0 degrees in terms of control. When the rotation shaft is rotated so that the capacitance becomes the minimum capacitance, the rotation is structurally stopped when the rotation angle corresponding to the minimum capacitance is reached. Therefore, the rotation angle at this time is defined as 0 degrees in terms of structure.

In addition, in order to set the rotation angle of the rotation shaft to 3,600 degrees in terms of control, the rotation angle of the rotation shaft is only required to once set to the rotation angle at which the capacitance becomes the maximum capacitance in terms of structure, and then set the rotation angle rotated by -1 to 3,600 degrees in terms of control. When the rotation shaft is rotated so that the capacitance becomes the maximum capacitance, the rotation is structurally stopped when the rotation angle corresponding to the maximum capacitance is reached. Therefore, the rotation angle at this time is defined as the maximum rotation angle in terms of structure.

With this configuration, the capacitance of the variable capacitor can be changed within a prescribed range. Such an operation is performed after the variable capacitor is first incorporated, after the variable capacitor is replaced, or the like. By performing this operation, it is possible to set the relationship between the rotation angle of the rotation shaft of the variable capacitor in terms of structure and the rotation angle in terms of control.

Note that it is satisfactory that either 0 degrees in terms of control or 3600 degrees in terms of control is known. Accordingly, in the present embodiment, the following description will be given assuming that the 0 degree in terms of control is set.

Note that the variable capacitor is not limited to a variable capacitor of a type in which the capacitance is changed by changing the positional relationship of the electrodes. For example, the variable capacitor may be a variable capacitor of a type in which the capacitors provided in plurality and connected in series to a switch are connected in parallel, and the overall capacitance is changed by changing the state (ON/OFF) of the switch.

The first driver 33 changes the position of the movable electrode of the first variable capacitor 321. The second driver 34 changes the position of the movable electrode of the second variable capacitor 322. The first driver 33 and the second driver 34 described above are each an example of a driver of the present invention.

The first driver 33 and the second driver 34 each include a motor and a driver for driving the motor. An output shaft of the motor is connected to the rotation shaft of the variable capacitor. When the output shaft of the motor rotates, the rotation shaft of the variable capacitor rotates to change the position of the movable electrode.

The motor is a stepping motor, for example. Naturally, it is also possible to use other types of motors (servo motors and the like) but the present embodiment will describe a case of using a stepping motor. Here, the stepping motor is a motor that rotates by moving in units of a certain angle. The corresponding driver receives a pulse signal output from the controller as a command signal, and operates the stepping motor based on the command signal. When the stepping motor is used in this manner, the position of the movable electrode can be easily understood when being expressed by the number of steps corresponding to the number of pulse signals given to the stepping motor. For example, in a case where the stepping motor needs to be changed by 1,000 steps when the rotation angle of the rotation shaft rotates to 0 to 3,600 degrees (10 rotations), the position of the movable electrode can be expressed by 0 to 1,000 steps.

The first position detector 35 detects the rotation angle of the first driver 33, and includes an encoder, for example. The detected rotation angle is output to the matching controller 39 as rotation angle information Dc1. Similarly, the second position detector 36 detects the rotation angle of the second driver 34, and includes an encoder, for example. The detected rotation angle is output to the matching controller 39 as rotation angle information Dc2.

The first position detector 35 and the second position detector 36 are each an example of the position acquire of the present invention.

As described above, the rotation angle of the first driver 33 and the rotation angle of the second driver 34 indirectly represent the position of the movable electrode of the variable capacitor. Accordingly, by detecting the rotation angle of the first driver 33, the position of the movable electrode of the variable capacitor can be detected. When the stepping motor is used as described above, the position of the movable electrode of the variable capacitor may be managed by the number of steps.

For example, when the rotation angle of the rotation shaft is 0 degrees in terms of control, the capacitance is the minimum capacitance in terms of control. Therefore, the position of the movable electrode of the variable capacitor at this time can be set to 0 step. In addition, when the rotation angle of the rotation shaft is 3,600 degrees in terms of control, the capacitance is the maximum capacitance in terms of control. Therefore, the position of the movable electrode of the variable capacitor at this time can be set to 1,000 steps. Naturally, the 0 to 1,000 steps described above as examples are merely examples, and for example, it is also allowable to have a configuration of 0 to 5000 steps.

In addition, as can be seen from the above, the position of the movable electrode, the rotation angle of the rotation shaft of the variable capacitor, and the rotation angle of the motor individually have a correspondence relationship with the capacitance of the variable capacitor, and thus the capacitance of the variable capacitor can be estimated by detecting any of these.

In the present embodiment, as an example, the capacitance of the variable capacitor is estimated by the rotation angle of the motor. The rotation angle of the motor can be expressed by the number of steps. Accordingly, when the minimum capacitance in terms of control is 0 steps and the maximum capacitance in terms of control is 1,000 steps, the capacitance of the variable capacitor can be expressed in terms of the number of steps like 0 to 1,000 steps.

In addition, in the case of the above example, the minimum capacitance in terms of structure is a capacitance at a rotation angle obtained by +1 rotation of the motor from a rotation angle of 0 degrees in terms of control, and thus corresponds to -100 steps in terms of control. Similarly, the maximum capacitance in terms of structure is a capacitance at a rotation angle obtained by rotating the motor by +1 rotation from a rotation angle of 3,600 degrees in terms of control, and thus corresponds to 1,100 steps in terms of control.

The matching controller 39 performs the matching operation using the load information IFL transmitted from the matcher communicator 44, the rotation angle information Dc1 output from the first position detector 35, and the rotation angle information Dc2 output from the second position detector 36.

For example, the command signals Sc1 and Sc2 are output for changing the capacitance C1 of the first variable capacitor 321 and the capacitance C2 of the second variable capacitor 322 inside the matching circuit 32 so that the reflection coefficient absolute value Γ approaches the target reflection coefficient absolute value Γ0 (normally 0).

In other words, the command signals Sc1 and Sc2 for changing the capacitance C1 of the first variable capacitor 321 and the capacitance C2 of the second variable capacitor 322 so as to decrease the reflected wave power are output.

As described above, the matcher communicator 44 communicates with the power source communicator 16 via the communication cable 73. Since this communication uses, for example, RS485 communication or communication using an optical fiber, it is possible to perform high-speed and stable information transmission.

The first driver 33 and the second driver 34 rotate the rotation shafts of the first variable capacitor 321 and the second variable capacitor 322 based on the command signals Sc1 and Sc2 output from the matching controller 39. By repeating such an operation, the absolute value Γ approaches the target reflection coefficient absolute value Γ0 (normally 0). In other words, the reflected wave power decreases. By performing such an operation, the matching operation is performed.

There are various methods in the matching operation. For example, the capacitance C1 of the first variable capacitor 321 and the capacitance C2 of the second variable capacitor 322, at which the reflection coefficient absolute value Γ is estimated to be closest to the target reflection coefficient absolute value Γ0 (normally 0) can be calculated, and the command signals Sc1 and Sc2 can be output to the first driver 33 and the second driver 34 with the capacitances as targets.

Even in performing such a matching operation, there are various ways of outputting the command signals Sc1 and Sc2. For example, when the difference between the current capacitance and the target capacitance is large, an intermediate capacitance between the current capacitance and the target capacitance may be set as the target capacitance. Although various other methods are disclosed, the method of the matching operation is not limited in the present embodiment.

In any case, the reflection coefficient absolute value Γ is controlled to approach the target reflection coefficient absolute value Γ0 (normally 0), in other words, controlled to decrease the reflected wave power.

In this manner, in the present embodiment, the common sensor 14 common to the high frequency power source 10 and the impedance matcher 30 is provided on the load side of the high frequency power output circuit 13, and the high frequency power source 10 and the impedance matcher 30 perform individual controls based on the information detected by the common sensor 14.

Therefore, there is no problem, which exists in the known technology, that a difference occurs in information (for example, a power value, a reflection coefficient) calculated based on the information detected by the dedicated sensors provided individually in the high frequency power source 10 and the impedance matcher 30. In addition, the sensors which have been individually required for the high frequency power source and the impedance matcher in the known technology can be reduced to one sensor, making it possible to reduce the installation space of the sensor, and reduce the cost.

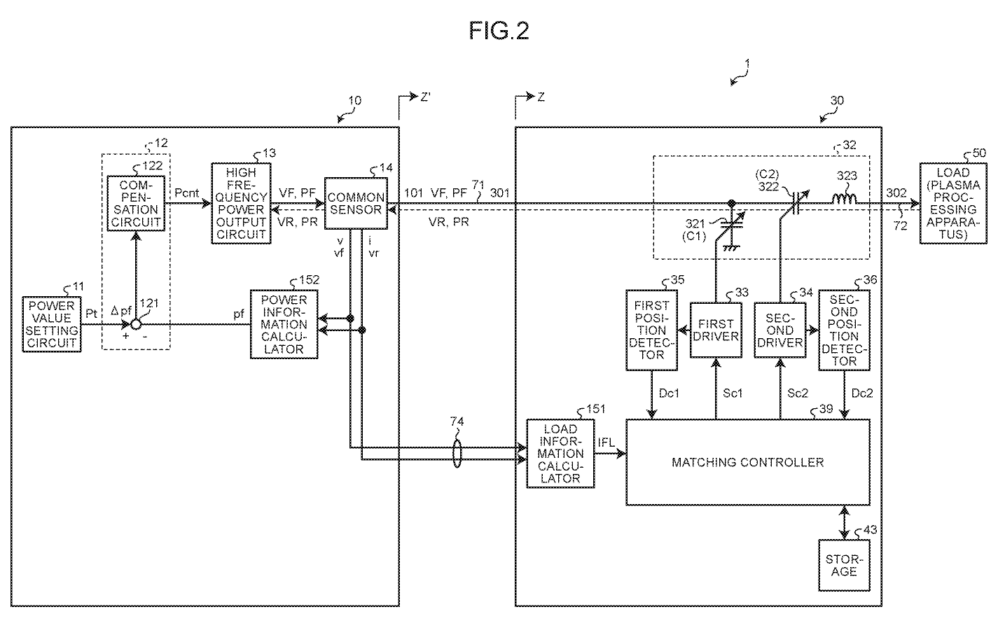

FIG. 2 is a diagram illustrating another configuration example of the high frequency power supply system.

In the configuration illustrated in FIG. 1, the load information calculator 151 and the power information calculator 152 are disposed in the high frequency power source 10. In contrast, the configuration illustrated in FIG. 2 is different in that the load information calculator 151 is disposed in the impedance matcher 30 while the power information calculator 152 is disposed in the high frequency power source 10. Accordingly, in the configuration illustrated in FIG. 2, while the detection signal detected by the common sensor 14 is input to the power information calculator 152 disposed in the high frequency power source 10, the detection signal is also input to the load information calculator 151 disposed in the impedance matcher 30 via a cable 74. Additionally, the configuration is different from the configuration illustrated in FIG. 1 in that the load information IFL calculated by the load information calculator 151 is input to the matching controller 39. Even with this configuration, an effect similar to that of the configuration of FIG. 1 can be obtained.

The cable 74 between the high frequency power source 10 and the impedance matcher 30 is preferably a coaxial multi-cable. The coaxial multi-cable is formed with a plurality of coaxial cables integrated into one cable. Therefore, even when transmitting a plurality of types of signals (for example, two types of forward wave voltage detection signal vf and reflected wave voltage detection signal vr, or two types of voltage detection signal v and current detection signal i), it is possible to transmit information without being affected by a difference in cable length (for example, phase shift).

The storage 43 is a storage including nonvolatile memory, and can hold stored data even when power is not supplied, such as an EEPROM. Note that the storage 43 is an example of a storage of the present invention.

The matching controller 39 can store the position information of the movable electrode of the variable impedance element and the position information of the winding in the storage 43. Further, the matching controller 39 can read the position information stored in the storage 43. As described above, the value converted into the number of steps (for example, 0 to 1,000 steps) can be used as the position information of the movable electrodes of the variable impedance element and the position information of the windings. The impedance matcher 30 also includes volatile memory (not illustrated), and can store information to be temporarily used. The matching circuit is not limited to the configuration illustrated in FIG. 1.

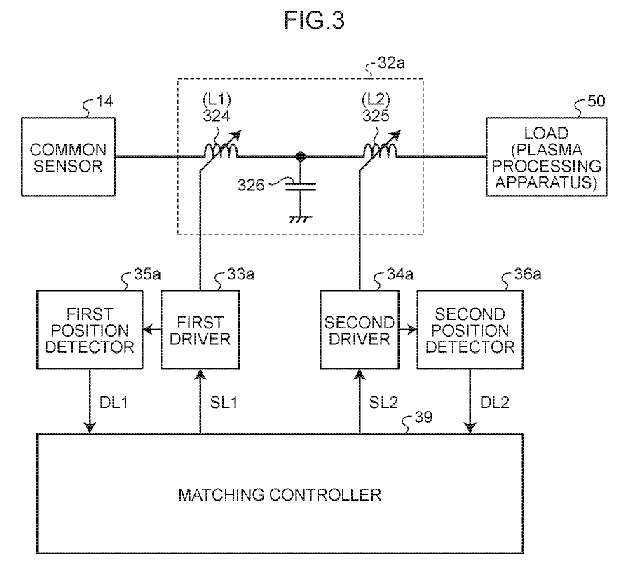

FIG. 3 is a diagram illustrating another configuration example of the matching circuit.

A matching circuit 32a of FIG. 3 includes: a first variable inductor 324 provided at the output end of the common sensor 14; a second variable inductor 325 provided between the output end of the first variable inductor 324 and the load 50; and a capacitor 326 provided between the output end of the first variable inductor 324 and the ground. The inductance of the first variable inductor 324 is represented by L1, and the inductance of the second variable inductor 325 is represented by L2. The capacitance of the capacitor 326 is a fixed value. In this manner, a variable inductor can also be used as the variable impedance element. In addition, FIG. 3 illustrates an example of using the capacitor 326 having a fixed capacitance value, but a variable capacitor may be used instead of the capacitor 326.

The variable inductor includes a fixed winding and a movable winding, for example, and can change inductance by changing a positional relationship of the movable winding with respect to the fixed winding. For example, a rotation shaft is connected to the movable winding, and rotating the rotation shaft by a driver such as a motor changes the positional relationship of the movable winding with respect to the fixed winding, causing a change in the inductance. That is, although there is a difference between the capacitance and the inductance, the inductance as a control target can be changed by changing the positional relationship regarding the windings by the driver such as a motor similarly to the variable capacitor.

Accordingly, as illustrated in FIG. 3, an inductance L1 of the first variable inductor 324 can be detected by changing the positional relationship regarding the windings of the first variable inductor 324 by a first driver 33a and detecting the rotation angle of the motor of the first driver 33a by the first position detector 35a. The detected rotation angle is output to the matching controller 39 as rotation angle information DL1.

Similarly, an inductance L2 of the second variable inductor 325 can be detected by changing the positional relationship regarding the windings of the second variable inductor 325 by a second driver 34a and detecting the rotation angle of the motor of the second driver 34a by the second position detector 36a. The detected rotation angle is output to the matching controller 39 as rotation angle information DL2.

Note that the first driver 33a, the second driver 34a, the first position detector 35a, and the second position detector 36a have different control targets, but have configurations similar to those of the first driver 33, the second driver 34a, the first position detector 35a, and the second position detector 36a illustrated in FIG. 1, respectively. Therefore, the description will be omitted.

In addition, similarly to the variable capacitor, the position of the movable winding, the rotation angle of the rotation shaft of the variable inductor, and the rotation angle of the motor individually have a correspondence relationship with the inductance of the variable inductor, and thus, it is possible to estimate the inductance of the variable inductor by detecting any of these. Therefore, similarly to the variable capacitor, the inductance of the variable inductor can be expressed in terms of the number of steps, for example, 0 to 1,000 steps.

Note that, although the rotation angle of the rotation shaft and the like are different between the variable inductor and the variable capacitor, concepts such as the minimum inductance in terms of structure and the minimum inductance in terms of control are similar to the minimum capacitance of the variable capacitor and the minimum capacitance in terms of control.

Although FIG. 1 illustrates an example in which there are two variable capacitors in the matching circuit 32, the number of variable capacitors is not limited. For example, one variable capacitor may be provided, or three or more variable capacitors may be provided. In addition, FIG. 3 illustrates an example in which there are two variable inductors in the matching circuit 32, but the number of variable inductors is not limited. For example, one variable inductor may be provided, or three or more variable inductors may be provided. Although not illustrated, one or more variable capacitors and one or more variable inductors may be mixed in the matching circuit 32.

Next, effects of the present embodiment will be described.

According to the high frequency power supply system of the present embodiment, since the common sensor (common sensor 14) is used in the high frequency power source 10 and the impedance matcher 30, there is no problem of having a difference in information (for example, a power value, a reflection coefficient) calculated based on information detected by dedicated sensors individually provided in the high frequency power source 10 and the impedance matcher 30 as in the known technology.

In addition, the sensors which have been individually required for the high frequency power source 10 and the impedance matcher in the known technology can be reduced to one sensor, making it possible to reduce the installation space of the sensor, and reduce the cost.

normally, the high frequency power source 10 and the impedance matcher 30 are separated into different housings. Therefore, when common sensor 14 is used, common sensor 14 needs to be disposed in one of the housings. In this case, the detection signal acquired by common sensor 14 or the information calculated using the detection signal needs to be transmitted into the other housing by some means (communication, cable connection, etc.).

However, the possibility of disconnection cannot be denied in either case of communication or cable connection. The disconnection occurring when the common sensor 14 is disposed in the impedance matcher would cause normal power value control in the high frequency power source to fail, leading to maximization of the output power value. In contrast, the disconnection occurring when common sensor 14 is disposed in the high frequency power source would cause an only slight decrease in matching accuracy. Therefore, it is preferable to dispose the common sensor 14 in the high frequency power source 10. Consequently, in the present embodiment, as illustrated in FIG. 1 and the like, the common sensor 14 is disposed in the high frequency power source 10.

According to the high frequency power supply system of the present disclosure, a common sensor is used in the high frequency power source and the impedance matcher, making it possible to suppress occurrence of a problem of having a difference in information (for example, a power value, a reflection coefficient) calculated based on information detected by the dedicated sensors provided individually in the high frequency power source and the impedance matcher as in the known technology.

In addition, the sensors which have been individually required for the high frequency power source and the impedance matcher in the known technology can be reduced to one sensor, making it possible to reduce the installation space of the sensor, and reduce the cost.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A high frequency power supply system, being configured to supply high frequency power to a load, the high frequency power supply system comprising:
a high frequency power output circuit that outputs high frequency power obtained by amplifying a high frequency signal;
a sensor provided on a load side of the high frequency power output circuit; and
a power controller that acquires information related to high frequency power calculated based on the information detected by the sensor, and controls a power value of the high frequency power output from a high frequency power source using the acquired information;
a matching circuit including at least one variable impedance element having electrodes and windings and having a variable positional relationship regarding the electrodes or between the winding;
a driver provided to change the positional relationship regarding the electrodes or regarding the windings; and
a matching controller that acquires a reflection coefficient or load-side impedance calculated based on the information detected by the sensor, and uses the acquired reflection coefficient or load-side impedance to give, to the driver, a command signal for changing the positional relationship regarding the electrodes or regarding the windings so as to decrease reflected wave power.

2. The high frequency power supply system according to claim 1,
the high frequency power supply system comprising:
a high frequency power source that outputs, toward the load, high frequency power obtained by amplifying a high frequency signal; and
an impedance matcher provided between the high frequency power source and the load,
wherein the high frequency power output circuit, the sensor, and the power controller are disposed in the high frequency power source, and
the matching circuit, the driver, and the matching controller are disposed in the impedance matcher.

3. The high frequency power supply system according to claim 2, further comprising:
a power information calculator that calculates information related to high frequency power output from the high frequency power output circuit based on the information detected by the sensor; and
a load information calculator that calculates and outputs a reflection coefficient or a load-side impedance based on the information detected by the sensor,
wherein the power information calculator and the load information calculator are disposed in the high frequency power source,
the power controller acquires information related to high frequency power from the power information calculator, and
the matching controller acquires the reflection coefficient or the load-side impedance from the load information calculator.

4. The high frequency power supply system according to claim 2, further comprising:
a power information calculator that calculates information related to high frequency power output from the high frequency power output circuit based on the information detected by the sensor; and
a load information calculator that calculates and outputs a reflection coefficient or a load-side impedance based on the information detected by the sensor,
wherein the power information calculator is disposed in the high frequency power source,
the load information calculator is disposed in the impedance matcher,
the power controller acquires information related to high frequency power from the power information calculator, and
the matching controller acquires the reflection coefficient or the load-side impedance from the load information calculator.

5. The high frequency power supply system according to claim 3,
wherein transmission of information performed between the high frequency power source and the impedance matcher is performed using a communicator.

6. The high frequency power supply system according to claim 4,
wherein transmission of information performed between the high frequency power source and the impedance matcher is performed using a communicator.

7. The high frequency power supply system according to claim 3,
wherein transmission of information performed between the high frequency power source and the impedance matcher is performed via a coaxial multi-cable.

8. The high frequency power supply system according to claim 4,
wherein transmission of information performed between the high frequency power source and the impedance matcher is performed via a coaxial multi-cable.
